(19) United States
(12) Patent Application Publication
(10) Pub. No.: US 2024/0202389 A1
(43) Pub. Date: Jun. 20, 2024

(54) SYSTEM AND METHOD FOR PATH ANALYSIS TO MANAGE COMPUTING RESOURCES

(71) Applicant: Dell Products L.P., Round Rock, TX (US)

(72) Inventors: IAN ROCHE, Glanmire (IE); PHILIP E. HUMMEL, San Jose, CA (US); DHARMESH M. PATEL, Round Rock, TX (US)

(21) Appl. No.: 18/068,761

(22) Filed: Dec. 20, 2022

(51) Int. Cl. G06F 30/20; G06V 40/10; G07C 11/00

(52) U.S. Cl. CPC G06F 30/20; G06V 40/10; G07C 11/00; G07C 2011/04

(57) ABSTRACT

Methods and systems for providing traffic management services are disclosed. To provide traffic management services in a manner that increases computational efficiency of hardware resources necessary to provide the traffic management services, a path manager may manage traffic management services based on fastest routes of individuals. To identify the fastest route of an individual, traversal times along routes between locations, in which the individual is to traverse, may be determined. These traversal times may be updated based on a population density observed using computer vision along the routes between the locations. Using the updated traversal times, a candidate fastest route may be determined, and the traffic may be managed based on the candidate fastest route.

### FIELD

Embodiments disclosed herein relate generally to traffic management services. More particularly, embodiments disclosed herein relate to systems and methods to prioritize allocation of resources of data processing systems based on the fastest route of individuals throughout a distributed environment.

### BACKGROUND

Computing devices may provide computer-implemented services. The computer-implemented services may be used by users of the computing devices and/or devices operably connected to the computing devices. The computer-implemented services may be performed with hardware components such as processors, memory modules, storage devices, and communication devices. The operation of these components may impact the performance of the computer-implemented services.

### BRIEF DESCRIPTION OF THE DRAWINGS

Embodiments disclosed herein are illustrated by way of example and not limitation in the figures of the accompanying drawings in which like references indicate similar elements.

FIG. 1 shows a block diagram illustrating a system in accordance with an embodiment.

FIG. 2A shows a diagram illustrating an environment in accordance with an embodiment.

FIG. 2B shows a graph data structure in accordance with an embodiment.

FIG. 3 shows a flow diagram illustrating a method for managing a data processing system in accordance with an embodiment.

FIG. 4 shows a block diagram illustrating a data processing system in accordance with an embodiment.

### DETAILED DESCRIPTION

Various embodiments will be described with reference to details discussed below, and the accompanying drawings will illustrate the various embodiments. The following description and drawings are illustrative and are not to be construed as limiting. Numerous specific details are described to provide a thorough understanding of various embodiments. However, in certain instances, well-known or conventional details are not described in order to provide a concise discussion of embodiments disclosed herein.

Reference in the specification to “one embodiment” or “an embodiment” means that a particular feature, structure, or characteristic described in conjunction with the embodiment can be included in at least one embodiment. The appearances of the phrases “in one embodiment” and “an embodiment” in various places in the specification do not necessarily all refer to the same embodiment.

In general, embodiments disclosed herein relate to methods and systems for providing, at least in part, traffic management services. To provide the traffic management services, a system may include any number of data processing systems. A data processing system may include a finite quantity of hardware resources in order to provide computer-implemented services to consumers of the traffic management services. The finite quantity of hardware resources may limit the quantity and types of computer-implemented services that may be provided at any point in time (e.g., limited tracking and analyzing of activities of individuals within an environment that may affect a traffic flow of the environment).

For example, to manage traffic in a dense environment, all moving and/or non-moving objects (e.g., individuals) may require some degree of tracking and analyzation (e.g., granular tracking and analyzation of the individuals).

Consequently, due to the finite quantity of hardware resources, such granular tracking and analyzation of the objects in the environment may limit the efficiency, effectiveness, and/or productivity of the system providing the granular tracking and analyzation. Subsequently, the activities of individuals which affect the traffic flow in the environment may go undetected and therefore present the possibility of traffic management inaccuracies (e.g., may cause an unsafe density of individuals in a specific location, leading to adverse effects such as injury and/or death).

In order to provide traffic management services in a manner that reduces the quantity of hardware resources necessary to provide the traffic management services, a path manager may prioritize traffic management services based on macro trends of individuals traversing through an environment (e.g., a population density of individuals traversing a route through the environment). The macro trends may indicate a level of traffic.

To identify the macro trends of the individuals, travel time estimates along routes between locations in the environment, in which an individual of the individuals is to traverse, may be determined. The travel time estimates may be based on a population density and/or an obstruction density (e.g., a number of objects) along the routes between the locations. These densities may be used as a macro trend of the macro trends to indicate a flow of traffic (“traffic flow”) along a route of the routes. The travel time estimates may further be based on amounts of time to complete traversal along the routes (referred to as “traversal times”, to be discussed further below) when there is negligible traffic flow.

Using the traversal times with the macro trends (e.g., using the time travel estimates), a fastest route (also referred to as “a candidate fastest route”) may be determined. The fastest route may be a route of the routes which takes the least amount of time to traverse to completion when compared to the other routes of the routes (e.g., The fastest route may have a lowest travel time estimate out of all the travel time estimates).

Thus, using the fastest route may allow for the management of traffic. For example, knowing a route which is faster to traverse than other routes may allow for redirection of individuals to traverse the faster route, thereby lessening the densities along more densely traversed routes.

By doing so, fewer hardware resources may be expended as traffic management may be simplified to counting individuals to identify the macro trends (e.g., population density along the routes), rather than individually tracking and analyzing all individuals in the environment. The traffic management services may then have more hardware resources readily available and therefore be more capable of increasing the quantity and types of the computer-implemented services that may be provided at any point in time. Accordingly, the cost and resources expended for providing traffic management services may be further reduced.

In an embodiment, a method for managing traffic flow in an environment based on macro trends is provided.

The method may include obtaining a graph, the graph representing the environment, the graph including: nodes that are associated with different locations in the environment; and edges connecting the nodes that represent traversal times between the different locations associated with the nodes; obtaining a macro trend of the macro trends, the macro trend indicating a level of traffic between two of the different locations, and the macro trend being obtained using computer vision; adjusting a travel time estimate of the traversal times between two nodes of the graph using the macro trend to obtain an updated graph, the two nodes of the graph representing the two of the different locations; performing a fastest route analysis using the updated graph to obtain a fastest route; and managing the traffic flow using the fastest route.

Obtaining the macro trend may include obtaining an image of a scene associated with an edge of the edges; and ingesting the image into an inference model to obtain the macro trend.

The macro trend may include one selected from a group consisting of a number of people in a queue in the scene; a number of people that pass by a point in the scene.

The inference model may be programmed to identify a number of people in the scene.

Adjusting the travel time estimate may include obtaining, using the macro trend, a variable level of delay (referred to as “the traversal times”); and obtaining a travel time estimate based on the variable level of delay and a static level of delay.

Obtaining the updated graph may include replacing a weight of an edge of the edges using the adjusted travel time estimate to obtain an updated edge of the edges.

The edge may connect the two nodes.

Performing the fastest route analysis may include using the updated edge to obtain the travel time estimate for a candidate fastest route.

In an embodiment, a non-transitory media is provided that may include instructions that when executed by a processor cause the computer-implemented method to be performed.

In an embodiment, a data processing system is provided that may include the non-transitory media and a processor and may perform the computer-implemented method when the computer instructions are executed by the processor.

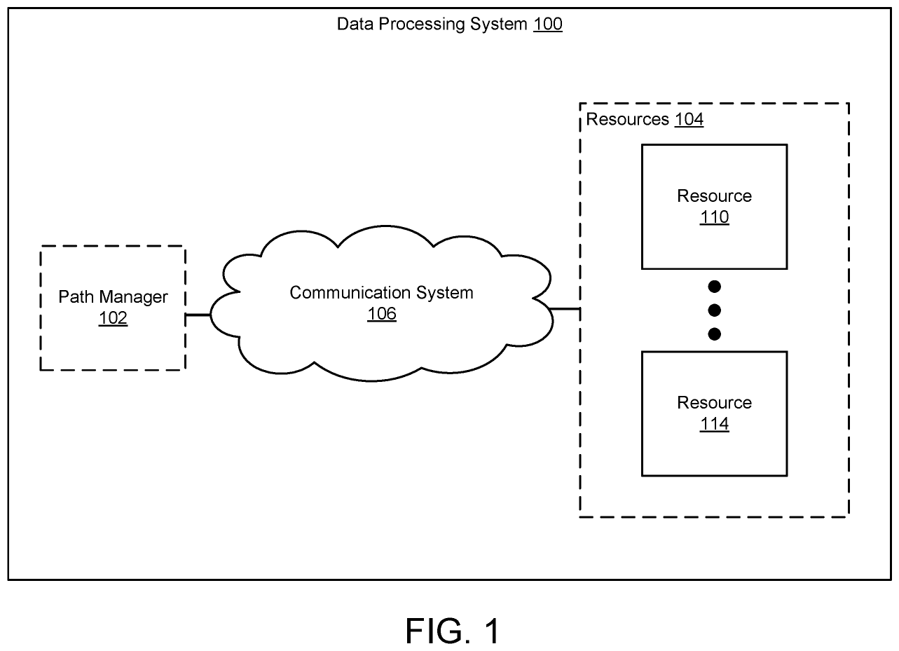

Turning to FIG. 1, a block diagram illustrating a system in accordance with an embodiment is shown. The system shown in FIG. 1 may provide computer-implemented services including database services, instant messaging services, traffic management services, and/or other types of computer-implemented services. The traffic management services may be provided by various portions of the system of FIG. 1.

The system may include, for example, data processing system 100. Data processing system 100 may provide, at least in part, the traffic management services.

Data processing system 100 may include a finite quantity of hardware resources in order to provide the computer-implemented services. However, the finite quantity of hardware resources may limit the quantity and types of computer-implemented services that may be provided at any point in time.

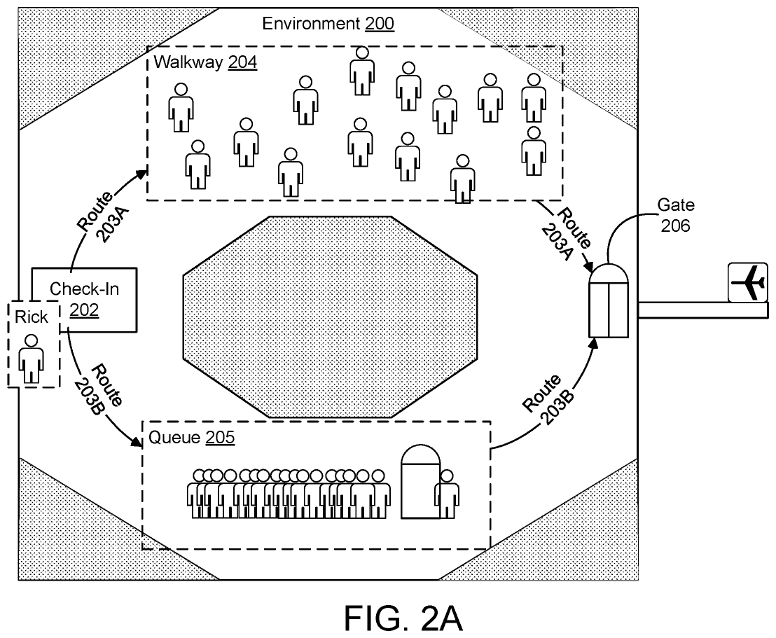

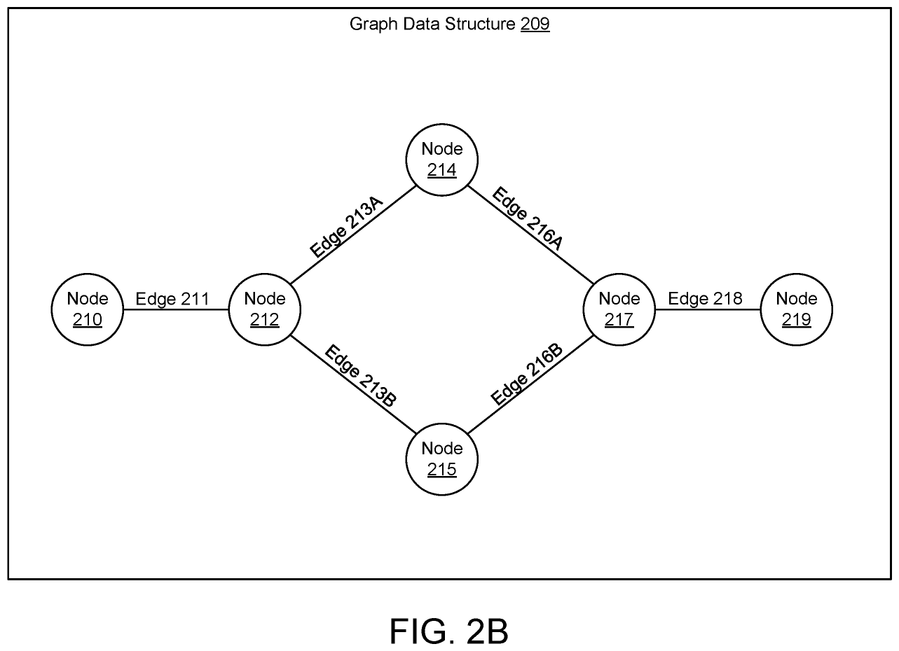

For example, providing the traffic management services may consume hardware resources such as processor cycles, memory space, storage space, etc. Accordingly, data processing system 100 may only be able to provide a limited quantity of the traffic management services. This limitation may prevent the system of 100 from granularly tracking and analyzing routes of all individuals within a predetermined area (e.g., environment 200 discussed with respect to FIG. 2A) at a desired level of tracking and analyzation sufficient to manage traffic flow.

Now, consider a scenario where a large number of individuals are located in a dense environment such as an airport. Locations in which the individuals traverse to, and the paths the individuals traverse along to arrive at the locations, in the airport may change over time. Additionally, the time in which traversal takes between the locations may change over time. To ascertain traffic flow in the airport, individuals may need to be tracked along all possible traversal routes. However, doing so may not be possible due to the finite quantity of hardware resources available to perform the tracking. Consequently, the routes traversed by the individuals, affecting the traffic flow in the environment, may go undetected and therefore present the possibility of traffic management inaccuracies (mentioned previously).

In general, embodiments disclosed herein may provide methods, systems, and/or devices for traffic management services in a manner that reduces the quantity of hardware resources necessary to provide the traffic management services. By doing so, the provided traffic management services may be more capable of accurately identifying and managing traffic flow in dense environments.

To provide the traffic management services, a system in accordance with an embodiment may prioritize traffic management services using the macro trends (previously mentioned) of individuals in an environment. By doing so, fewer hardware resources may be expended for providing the traffic management services compared to granular tracking of all the individuals in the environment. Accordingly, the computational efficiency for providing the traffic management services may be improved (e.g., when compared to scenarios in which performance of the traffic management services are not prioritized).

To obtain the macro trends of the individuals, routes of the individuals through an environment may be monitored. A count may be performed to obtain a number of individuals traversing the routes, and the macro trends (e.g., the density of individuals traversing the routes) may be obtained based on the count. In the context of an airport environment, for example, the routes may begin at check-in stations and end at departure gates from which individuals board departing planes. In this example, the macro trends may include the quantity of individuals traversing the routes.

Traffic management services may be prioritized by using the macro trends to obtain a candidate fastest route (to be discussed further below). The candidate fastest route may then be used to manage traffic flow (e.g., redirect traffic) to less dense routes in the environment. Doing so simplifies traffic management services by not requiring granular tracking and analyzation.

By simplifying traffic management services using the macro trends, computational efficiency may increase when providing traffic management services with limited hardware resources available.

For example, in the context of the airport environment, a person may need to traverse from a check-in station to a gate specified by a ticket they purchased at the airport. There may be two different routes to the gate, route A and route B. A count may be performed to determine the macro trend along each route of the routes. It may be determined that the candidate fastest route is route B, taking approximately 15 minutes less to traverse due to there being less people traversing along route B (less people counted traversing route B). The person may then be redirected to traverse route B to avoid increasing the traffic along route A.

To redirect the person, various downstream processes may be deployed to track and notify the person thereby preferentially directing the use of the limited hardware resources to manage traffic flow.

To provide its functionality as part of the system, data processing system 100 may include path manager 102, resources 104, and communication system 106. Each of these components is discussed below.

Path manager 102 may provide all, or a portion, of the computer-implemented services including the traffic management services. For example, path manager 102 may provide computer-implemented services to users of path manager 102 and/or other computing devices operably connected to path manager 102.

When providing the computer-implemented services, path manager 102 may (i) obtain a graph representing an environment in which a person traverses, (ii) obtain macro trends (or a macro trend of the macro trends) indicating traffic flow and/or a level of traffic in the environment, (iii) adjust travel time estimates for routes in the environment based on the macro trends, (iv) perform a fastest route analysis using the adjusted travel time estimates to obtain a fastest route, and (v) manage the traffic flow using the fastest route obtained.

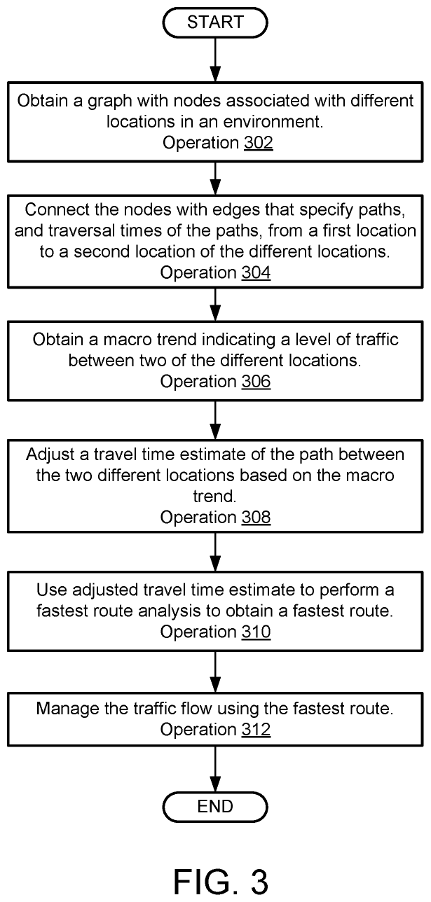

When performing its functionality, path manager 102 may perform all, or a portion, of the methods and/or actions shown in FIGS. 2A-3.

Resources 104 may include any number of resources (e.g., 110-114). For example, resources 104 may include one resource (e.g., 110) or multiple resources (e.g., 110-114) that may independently and/or cooperatively facilitate identification of the individuals, locations of the individuals, and/or notification to the individuals to redirect the individuals based on traffic flow in the locations.

All, or a portion, of resources 104 may provide computer-implemented services to users and/or other computing devices operably connected to resources 104. The computer-implemented services may include any type and quantity of services including, for example, identifying of locations of individuals at various points in time. Different resources may provide similar and/or different computer-implemented services.

To provide their functionality, resources 104 may (i) obtain instances of any number of individuals traversing through the environment along respective routes (e.g., images of scenes depicting the respective routes, to be discussed further below), and/or (ii) be used to facilitate management of traffic flow. For example, resources 104 may be used to facilitate management of traffic flow by including devices such as cameras, monitors, and/or loudspeakers, to notify individuals of the traffic flow in the environment.

In an embodiment, any of resources 104 are implemented using, for example, radio frequency tag identifiers (e.g., that may read tickets or other person-carried items), cameras (e.g., video/picture cameras implemented with various optical sensors), monitors (e.g., visual display devices to communicate visually with individuals in the environment) and/or other types of devices that may be used to identify the number of individuals within an environment and/or manage traffic flow based on the number.

When performing its functionality, any of resources 104 may perform all, or a portion, of the methods and/or actions shown in FIGS. 2A-3.

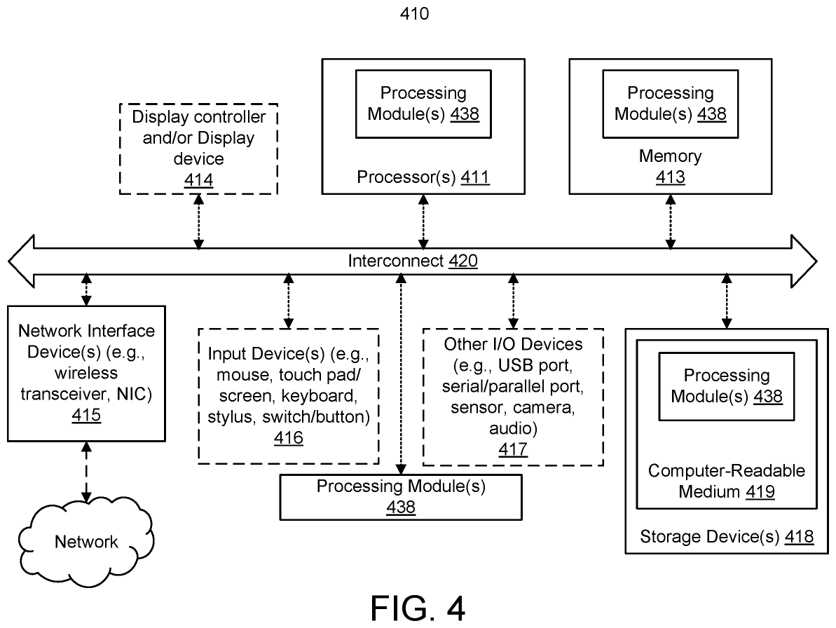

Path manager 102 and/or resources 104 may be implemented using a computing device such as a host or a server, a personal computer (e.g., desktops, laptops, and tablets), a “thin” client, a personal digital assistant (PDA), a Web enabled appliance, a mobile phone (e.g., Smartphone), an embedded system, local controllers, an edge node, and/or any other type of data processing device or system. For additional details regarding computing devices, refer to FIG. 4.

Any of the components illustrated in FIG. 1 may be operably connected to each other (and/or components not illustrated) with a communication system 106. In an embodiment, communication system 106 may include one or more networks that facilitate communication between any number of components. The networks may include wired networks and/or wireless networks (e.g., and/or the Internet). The networks may operate in accordance with any number and types of communication protocols (e.g., such as the internet protocol).

While illustrated in FIG. 1 as including a limited number of specific components, a system in accordance with an embodiment may include fewer, additional, and/or different components than those illustrated therein.

To further clarify embodiments disclosed herein, an example implementation in accordance with an embodiment is shown in FIG. 2A. This figure shows a diagram illustrating an environment in which traffic management services may be provided. While described with respect to traffic management services, it will be understood that embodiments disclosed herein are broadly applicable to different use cases as well as different types of data processing systems than those described below.

Turning to FIG. 2A, consider a scenario in which an airport includes video surveillance cameras (e.g., limited hardware resources located within an environment). The cameras (not explicitly shown in FIG. 2A) may be configured to visually identify one or more individuals within an environment and count the number of individuals identified using computer vision. The video surveillance cameras may collect data about location points (e.g., images of scenes) and corresponding routes, to and from the location points, for the individuals traversing through the environment. The video surveillance cameras may further send the collected data to a security system (a computer operating system such as path manager 102 hosted on a data processing system, such as data processing system 100) to analyze the collected data in order to make decisions regarding management of traffic flow in the environment.

As shown in FIG. 2A, an individual, named Rick, may be scheduled for a flight departing from George Bush Intercontinental/Houston Airport (e.g., environment 200) at 8:30 a.m. and arriving at another airport (e.g., Orlando International Airport) by 12:00 p.m. the same day. Rick is scheduled to begin boarding an airplane located at Gate 206 starting at 8:00 a.m.

Environment 200 may include any number of resources (e.g., resources 110-114). Resource 110 (not explicitly shown in FIG. 2A) may be a security camera that identifies Rick at a first location (e.g., check-in 202) at a first point in time (e.g., at 5:45 a.m.). To get to gate 206, Rick may traverse one of two potential routes.

The potential routes include route 203A and route 203B. Rick may follow one of the two potential routes by traversing from a start position (e.g., check-in 202) to a presumed stop position (e.g., Gate 206). Route 203A, indicated by two arrows: (i) a first arrow moving from check-in 202 to walkway 204, and (ii) a second arrow from walkway 204 to gate 206, may require Rick to traverse through walkway 204. Route 203B, indicated by two arrows: (i) a third arrow moving from check-in 202 to queue 205, and (ii) a fourth arrow from queue 205 to gate 206, may require Rick to traverse through queue 205.

In this example, the potential routes (e.g., 203A and 203B) may be monitored by respective security cameras (similar to resource 110 and not explicitly shown in FIG. 2A). The respective security cameras may use computer vision to identify a first number of individuals traversing route 203A (e.g., the individuals included in walkway 204), and to also identify a second number of individuals traversing route 203B (e.g., the individuals included in queue 205). The respective security cameras may use computer vision by counting the individuals to obtain the first number and the second number.

To do so, the respective security cameras may obtain images of scenes along the routes. These images may then be ingested into, for example, an inference model trained to obtain macro trends based off the ingested images. In an embodiment, a macro trend may be a number of people that pass a point in a scene depicted by an image of the images. By doing so, the inference model may identify the number of people in the scene.

Assume, for example, the respective security cameras count 14 individuals included in the area bound by walkway 204 (traversing along route 203A), and 18 individuals included in the area bound by queue 205 (traversing along route 203B). This first and second number, respectively, may be used to determine a candidate fastest route.

Assume in this example, based on the first number being 14 and the second number being 18, that the first number may represent a lighter traffic flow along route 203A when compared to the traffic flow along route 203B. The lighter traffic flow may indicate a candidate fastest route through walkway 204. The security system may obtain the candidate fastest route by using a graph data structure (to be discussed with respect to FIG. 2B) and the macro trends obtained (e.g., the first and the second numbers). After obtaining the candidate fastest route, the previously mentioned various downstream processes may be deployed to track and notify Rick of the candidate fastest route. These various downstream processes may be implemented by the security system utilizing various resources 110-114 (e.g., monitors, loudspeakers, etc.) to communicate the candidate fastest route to Rick and/or redirect Rick to traverse the candidate fastest route as Rick traverses from check-in 202 to gate 206.

While illustrated in FIG. 2A as including a specific scenario with a limited number of specific components, a system in accordance with an embodiment may include fewer, additional, and/or different components in same and/or different environment than those illustrated therein.

To further clarify embodiments disclosed herein, a graph data structure in accordance with an embodiment is shown in FIG. 2B. The graph data structure may illustrate how data is used by the data processing system to obtain the candidate fastest route within the system of FIG. 1.

Turning to FIG. 2B, a graph data structure in accordance with an embodiment is shown. In FIG. 2B, graph data structure 209 may be a representation of environment 200 from FIG. 2A. Each node may correspond with respective different locations within environment 200, and each edge may correspond with individual routes between the different locations. As discussed in the previous example of FIG. 2A, the security system may obtain the candidate fastest route by using a graph data structure.

To do so, the graph data structure (henceforth referred to as “the graph”) may first be obtained. The graph data structure may be obtained when generated by the security system using resources 104 to map environment 200 in a way that is intelligible to machines. In some embodiments, the graph may be obtained by a different data processing system that is operably connected to (e.g., in communication with) the security system.

In order to map environment 200, the security system may place nodes in specific spots on the graph to correspond with the different locations within environment 200. The different locations, and routes connecting the different locations, may be determined using resources 110-114 (e.g., the respective security cameras). In FIG. 2B, for example, (i) node 210 may correspond with check-in 202, (ii) node 212 may correspond with a first location where route 203A and route 203B split into separate routes, (iii) node 214 may correspond with the middle of walkway 204, (iv) node 215 may correspond with the middle of queue 205, (v) node 217 may correspond with a second location where route 203A and route 203B reconverge into a single route, and (vi) node 219 may correspond with gate 206. Each edge (e.g., 211, 213A-B, 216A-B, and 218) may connect these locations as illustrated in FIG. 2B.

These edges may each have an associated weight (discussed further with respect to FIG. 3) that influences a default traversal time. These default traversal times may be established during training of the security system (training of the inference model), and/or may change periodically as changes in environment 200 are observed over time. In an embodiment, a default traversal time of the default traversal times may specify an amount of time to complete traversal of a corresponding route (e.g., one of edges 211, 213A-B, 216A-B, and/or 218).

Once mapping of the environment is complete, the macro trends may be obtained as described in the example scenario illustrated by FIG. 2A.

Using the macro trends, adjusted travel time estimates may be obtained and used to update the graph (e.g., replace/update the default traversal times of the corresponding routes). An adjusted travel time estimate of the estimates is discussed further with respect to FIG. 3.

The adjusted travel time estimates may lead to an updated graph that reflects the adjusted travel time estimates and the macro trends observed by the security system.

To obtain the candidate fastest route, a fastest route analysis may be performed. The fastest route analysis may be performed by summing the adjusted travel time estimates of each possible sequence of route traversal from node 210 to node 219.

Continuing the scenario above, for example, the possible sequence of route traversal may include (i) traversing edge 211, then edge 213A, then edge 216A, and then edge 218, and (ii) traversing edge 211, then edge 213B, then edge 216B, and then edge 218. Assume that edge 211 has a weight of 10, edge 213A has a weight of 2, edge 213B has a weight of 5, 216A has a weight of 9, edge 216B has a weight of 3, and edge 218 has a weight of 10. Assume that each edge has a same default traversal time. In this example, the first possible sequence of route traversal may have a sum weight of 31, and the second possible sequence of route traversal may have a sum weight of 28. The lower weight of the second possible sequence may indicate that the corresponding route of environment 200 (route 203B) is the candidate fastest route.

As discussed above, the components of FIGS. 1-2B may perform various methods to provide traffic management services in a manner that reduces the quantity of hardware resources necessary to provide the traffic management services. FIG. 3 illustrates a method that may be performed by the components of FIGS. 1-2B. In the diagrams discussed below and shown in these figures, any of the operations may be repeated, performed in different orders, omitted, and/or performed in parallel with or a partially overlapping in time manner with other operations.

Turning to FIG. 3, a flow diagram illustrating a method of managing a data processing system in accordance with an embodiment is shown. The method may be performed, for example, by a data processing system, a path manager, a communication system, resources, and/or other components illustrated in FIGS. 1-2B.

At operation 302, a graph (also referred to as a “graph data structure” when stored) with nodes associated with different locations in an environment is obtained. The graph may be obtained by first determining the environment and mapping the environment out in a way that is intelligible to machines. The environment may be any space in which resources (e.g., 104) have been implemented to track and/or analyze individuals in the space using computer vision. In an embodiment, the environment is an airport, as discussed in previous examples. The nodes may be mapped on the graph to represent (hence be associated with) the different locations.

The graph may be obtained by reading the graph from storage or memory, if already available (e.g., mappings between nodes and edges to the environment already complete). Likewise, the graph may be obtained from another device.

At operation 304, the nodes are connected with edges that specify routes, and traversal times of the routes, between the different locations. The nodes may be connected with the edges by, for example, graphically connecting two nodes of the nodes to one another on the graph with a line that is to be a visual representation of an edge of the edges. These relationships may also be stored as part of a corresponding graph data structure, which may be organized using any organizational technique. Additionally, the edges may each have a weight associated, previously mentioned with respect to FIG. 2B. The weight may be influenced by a level of traffic (indicated by macro trends) along each corresponding route of the routes.

In an embodiment, these traversal times are referred to as default traversal times. The traversal times (e.g., default traversal times) may be established based on observations of past individuals' traversal(s) of the routes (e.g., an inference model may be trained to determine default traversal time(s) based on observed traversal of the routes between the different locations). The traversal times may be further established under an assumption that there is either no traffic and/or a same (equal) level of traffic along each route when compared across all the routes.

For example, assume routes B, C, and D are all possible routes to efficiently traverse to a location E from a location A. A traversal time for each of these routes may be established only when the level of traffic for each route is equal to a constant, or at a predetermined level. The constant may be any value representing any number.

The constant may be established as equal to the number one. Hence, traversal times may be based on observations of a past individual's traversal(s) of the routes when the individual is the only individual traversing each of the routes, and/or based on observations of past individuals' traversal(s) of the routes when any single individual of the individuals is the only individual traversing one or more of the routes.

At operation 306, a macro trend, indicating the level of traffic between two of the different locations (e.g., the level of traffic along the route from a first location of the two different locations to a second location of the two different locations), is obtained as described with respect to FIG. 2A. For example, the macro trend may be obtained by using computer vision to identify one or more individuals. The identified individuals may then be counted to obtain a traffic number. This traffic number may indicate the level of traffic (previously referred to as “traffic flow”) between the two different locations, and as such, may be used as the macro trend (e.g., the macro trend of the route between/connecting the two different locations). In an embodiment, another macro trend may be determined for each route associated with one of the edges.

As mentioned with respect to operation 304, the weight of each edge may be influenced by the level of traffic along each corresponding route of each edge.

At operation 308, a travel time estimate of the path between the two different locations is adjusted based on the macro trend. The travel time estimate may be obtained by using a relationship between the macro trend and a travel time. The relationships may be, for example, a functional relationship. The functional relationship may take the macro trend as input and may output the travel time estimate.

Depending on features along a path, different functional relationships may be used to calculate travel time estimates between two different locations. For example, presence of a security check queue along a path may cause a greater delay in travel time when compared to an empty hallway along a path.

The functional relationships may be established based on historic data. For example, for a select number of individuals traversing along a path, their travel time may be calculated as well as the macro trend for the path during the traversals along the path. A functional relationship may then be established based on the relationships between travel time and macro trend (e.g., through regression or other method). The relationship may then be used to estimate travel time for a path based on a macro trend identified for the path. These functional relationships may be established via any process, and for any number and types of paths that may have similar or different features along the paths. The functional relationships may be established in advance of attempting to establish travel time estimates.

The travel time estimate may then be used to update the weight of the edge associated with the path between the two different locations. By updating the weight of the edge associated with the path, an updated graph may be obtained that reflects the real-time (or recent) travel time estimate for a path. Any number of travel time estimates may be updated to obtain the updated graph.

At operation 310, the adjusted travel time estimate is used to perform the fastest route analysis to obtain a fastest route (sometimes referred to as a “candidate fastest route”). The fastest route analysis may be completed, and the fastest route obtained, by using the graph similarly to how utilization of the graph is described (e.g., how the fastest route analysis is described) with respect to FIG. 2B.

At operation 312, the traffic flow is managed using the fastest route. The fastest route may be managed by the various downstream processes previously discussed. For example, the traffic flow may be managed by providing persons traversing the environment with path recommendations. The path recommendations may direct the persons along the fastest path, attempt to balance traffic between paths (e.g., even if not the fastest path), and/or may be provided to meet other types of goals.

The method may end following operation 312.

Using the method illustrated in FIG. 3, embodiments disclosed herein may facilitate computationally efficient management of traffic flow in an environment. By using macro trends to manage traffic flow, rather than through granular tracking of individuals traversing an environment, the computing resource cost for managing traffic flow may be reduced. For example, by using computer visions to obtain person counts rather than locations of large numbers of persons, both the quantity of data and number of computations to obtain the macro count may be greatly reduced when compared to person level tracking (e.g., via person communication device tracking or other techniques). Thus, the disclosed embodiments may provide a system that more efficiently marshals limited resources for managing traffic, and may facilitate deployment of other services that may otherwise not be available due to consumption of computing resources for traffic management.

Any of the components illustrated in FIGS. 1-3 may be implemented with one or more computing devices. Turning to FIG. 4, a block diagram illustrating an example of a data processing system (e.g., a computing device) in accordance with an embodiment is shown. For example, system 410 may represent any of data processing systems described above performing any of the processes or methods described above. System 410 can include many different components. These components can be implemented as integrated circuits (ICs), portions thereof, discrete electronic devices, or other modules adapted to a circuit board such as a motherboard or add-in card of the computer system, or as components otherwise incorporated within a chassis of the computer system. Note also that system 410 is intended to show a high-level view of many components of the computer system. However, it is to be understood that additional components may be present in certain implementations and furthermore, different arrangement of the components shown may occur in other implementations. System 410 may represent a desktop, a laptop, a tablet, a server, a mobile phone, a media player, a personal digital assistant (PDA), a personal communicator, a gaming device, a network router or hub, a wireless access point (AP) or repeater, a set-top box, or a combination thereof. Further, while only a single machine or system is illustrated, the term “machine” or “system” shall also be taken to include any collection of machines or systems that individually or jointly execute a set (or multiple sets) of instructions to perform any one or more of the methodologies discussed herein.

In one embodiment, system 410 includes processor 411, memory 413, and devices 415-417 via a bus or an interconnect 420. Processor 411 may represent a single processor or multiple processors with a single processor core or multiple processor cores included therein. Processor 411 may represent one or more general-purpose processors such as a microprocessor, a central processing unit (CPU), or the like. More particularly, processor 411 may be a complex instruction set computing (CISC) microprocessor, reduced instruction set computing (RISC) microprocessor, very long instruction word (VLIW) microprocessor, or processor implementing other instruction sets, or processors implementing a combination of instruction sets. Processor 411 may also be one or more special-purpose processors such as an application specific integrated circuit (ASIC), a cellular or baseband processor, a field programmable gate array (FPGA), a digital signal processor (DSP), a network processor, a graphics processor, a network processor, a communications processor, a cryptographic processor, a co-processor, an embedded processor, or any other type of logic capable of processing instructions.

Processor 411, which may be a low power multi-core processor socket such as an ultra-low voltage processor, may act as a main processing unit and central hub for communication with the various components of the system. Such processor can be implemented as a system on chip (SoC). Processor 411 is configured to execute instructions for performing the operations discussed herein. System 410 may further include a graphics interface that communicates with optional graphics subsystem 414, which may include a display controller, a graphics processor, and/or a display device.

Processor 411 may communicate with memory 413, which in one embodiment can be implemented via multiple memory devices to provide for a given amount of system memory. Memory 413 may include one or more volatile storage (or memory) devices such as random-access memory (RAM), dynamic RAM (DRAM), synchronous DRAM (SDRAM), static RAM (SRAM), or other types of storage devices. Memory 413 may store information including sequences of instructions that are executed by processor 411, or any other device. For example, executable code and/or data of a variety of operating systems, device drivers, firmware (e.g., input output basic system or BIOS), and/or applications can be loaded in memory 413 and executed by processor 411. An operating system can be any kind of operating systems, such as, for example, Windows® operating system from Microsoft®, Mac OS®/iOS® from Apple, Android® from Google®, Linux®, Unix®, or other real-time or embedded operating systems such as VxWorks.

System 410 may further include IO devices such as devices (e.g., 415, 415, 417, 418) including network interface device(s) 415, optional input device(s) 415, and other optional IO device(s) 417. Network interface device(s) 415 may include a wireless transceiver and/or a network interface card (NIC). The wireless transceiver may be a WiFi transceiver, an infrared transceiver, a Bluetooth transceiver, a WiMax transceiver, a wireless cellular telephony transceiver, a satellite transceiver (e.g., a global positioning system (GPS) transceiver), or other radio frequency (RF) transceivers, or a combination thereof. The NIC may be an Ethernet card.

Input device(s) 415 may include a mouse, a touch pad, a touch sensitive screen (which may be integrated with a display device of optional graphics subsystem 414), a pointer device such as a stylus, and/or a keyboard (e.g., physical keyboard or a virtual keyboard displayed as part of a touch sensitive screen). For example, input device(s) 415 may include a touch screen controller coupled to a touch screen. The touch screen and touch screen controller can, for example, detect contact and movement or break thereof using any of a plurality of touch sensitivity technologies, including but not limited to capacitive, resistive, infrared, and surface acoustic wave technologies, as well as other proximity data collector arrays or other elements for determining one or more points of contact with the touch screen.

IO devices 417 may include an audio device. An audio device may include a speaker and/or a microphone to facilitate voice-enabled functions, such as voice recognition, voice replication, digital recording, and/or telephony functions. Other IO devices 417 may further include universal serial bus (USB) port(s), parallel port(s), serial port(s), a printer, a network interface, a bus bridge (e.g., a PCI-PCI bridge), data collector(s) (e.g., a motion data collector such as an accelerometer, gyroscope, a magnetometer, a light data collector, compass, a proximity data collector, etc.), or a combination thereof. IO device(s) 417 may further include an imaging processing subsystem (e.g., a camera), which may include an optical data collector, such as a charged coupled device (CCD) or a complementary metal-oxide semiconductor (CMOS) optical data collector, utilized to facilitate camera functions, such as recording photographs and video clips. Certain data collectors may be coupled to interconnect 420 via a data collector hub (not shown), while other devices such as a keyboard or thermal data collector may be controlled by an embedded controller (not shown), dependent upon the specific configuration or design of system 410.

To provide for persistent storage of information such as data, applications, one or more operating systems and so forth, a mass storage (not shown) may also couple to processor 411. In various embodiments, to enable a thinner and lighter system design as well as to improve system responsiveness, this mass storage may be implemented via a solid-state device (SSD). However, in other embodiments, the mass storage may primarily be implemented using a hard disk drive (HDD) with a smaller amount of SSD storage to act as an SSD cache to enable non-volatile storage of context state and other such information during power down events so that a fast power up can occur on re-initiation of system activities. Also, a flash device may be coupled to processor 411, e.g., via a serial peripheral interface (SPI). This flash device may provide for non-volatile storage of system software, including a basic input/output software (BIOS) as well as other firmware of the system.

Storage device 418 may include computer-readable storage medium 419 (also known as a machine-readable storage medium or a computer-readable medium) on which is stored one or more sets of instructions or software (e.g., processing module, unit, and/or processing module/unit/logic 438) embodying any one or more of the methodologies or functions described herein. Processing module/unit/logic 438 may represent any of the components described above. Processing module/unit/logic 438 may also reside, completely or at least partially, within memory 413 and/or within processor 411 during execution thereof by system 410, memory 413 and processor 411 also constituting machine-accessible storage media. Processing module/unit/logic 438 may further be transmitted or received over a network via network interface device(s) 415.

Computer-readable storage medium 419 may also be used to store some software functionalities described above persistently. While computer-readable storage medium 419 is shown in an exemplary embodiment to be a single medium, the term “computer-readable storage medium” should be taken to include a single medium or multiple media (e.g., a centralized or distributed database, and/or associated caches and servers) that store the one or more sets of instructions. The terms “computer-readable storage medium” shall also be taken to include any medium that is capable of storing or encoding a set of instructions for execution by the machine and that cause the machine to perform any one or more of the methodologies of embodiments disclosed herein. The term “computer-readable storage medium” shall accordingly be taken to include, but not be limited to, solid-state memories, and optical and magnetic media, or any other non-transitory machine-readable medium.

Processing module/unit/logic 438, components and other features described herein can be implemented as discrete hardware components or integrated in the functionality of hardware components such as ASICS, FPGAs, DSPs or similar devices. In addition, processing module/unit/logic 438 can be implemented as firmware or functional circuitry within hardware devices. Further, processing module/unit/logic 438 can be implemented in any combination hardware devices and software components.

Note that while system 410 is illustrated with various components of a data processing system, it is not intended to represent any particular architecture or manner of interconnecting the components as such details are not germane to embodiments disclosed herein. It will also be appreciated that network computers, handheld computers, mobile phones, servers, and/or other data processing systems which have fewer components, or perhaps more components may also be used with embodiments disclosed herein.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as those set forth in the claims below, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments disclosed herein also relate to an apparatus for performing the operations herein. Such a computer program is stored in a non-transitory computer readable medium. A non-transitory machine-readable medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices).

The processes or methods depicted in the preceding figures may be performed by processing logic that comprises hardware (e.g., circuitry, dedicated logic, etc.), software (e.g., embodied on a non-transitory computer readable medium), or a combination of both. Although the processes or methods are described above in terms of some sequential operations, it should be appreciated that some of the operations described may be performed in a different order. Moreover, some operations may be performed in parallel rather than sequentially.

Embodiments disclosed herein are not described with reference to any particular programming language. It will be appreciated that a variety of programming languages may be used to implement the teachings of embodiments disclosed herein.

In the foregoing specification, embodiments have been described with reference to specific exemplary embodiments thereof. It will be evident that various modifications may be made thereto without departing from the broader spirit and scope of the embodiments disclosed herein as set forth in the following claims. The specification and drawings are, accordingly, to be regarded in an illustrative sense rather than a restrictive sense.

What is claimed is:

1. A method for managing traffic flow in an environment based on macro trends, the method comprising:
obtaining a graph, the graph representing the environment, the graph comprising:
nodes that are associated with different locations in the environment, and
edges connecting the nodes, the edges representing traversal times between the different locations;
obtaining a macro trend of the macro trends, the macro trend indicating a level of foot traffic between two of the different locations, and the macro trend being obtained using computer vision;
adjusting a travel time estimate of one or more travel time estimates between two nodes of the graph using the macro trend to obtain an updated graph, the two nodes of the graph representing the two of the different locations;
performing a fastest route analysis using the updated graph to obtain a fastest route; and
managing the traffic flow using the fastest route.

2. The method of claim 1, wherein obtaining the macro trend comprises:
obtaining an image of a scene associated with an edge of the edges; and
ingesting the image into an inference model to obtain the macro trend.

3. The method of claim 2, wherein the macro trend comprises one selected from a group consisting of:
a number of people in a queue in the scene; and
a number of people that pass by a point in the scene.

4. The method of claim 2, where the inference model is programmed to identify a number of people in the scene.

5. The method of claim 1, wherein adjusting the travel time estimate comprises:
obtaining, using the macro trend, a variable level of delay; and
obtaining the travel time estimate based on the variable level of delay and a static level of delay.

6. The method of claim 5, wherein obtaining the updated graph comprises replacing a weight of an edge of the edges using the adjusted travel time estimate to obtain an updated edge of the edges.

7. The method of claim 6, wherein the edge connects the two nodes.

8. The method of claim 6, wherein performing a fastest route analysis comprises:
using the updated edge to obtain a travel time estimate for a candidate fastest route.

9. A non-transitory machine-readable medium having instructions stored therein, which when executed by a processor, cause the processor to perform operations for managing traffic flow in an environment based on macro trends, the operations comprising:
obtaining a graph, the graph representing the environment, the graph comprising:
nodes that are associated with different locations in the environment, and
edges connecting the nodes, the edges representing traversal times between the different locations associated with the nodes;
obtaining a macro trend of the macro trends, the macro trend indicating a level of foot traffic between two of the different locations, and the macro trend being obtained using computer vision;
adjusting a travel time estimate of one or more travel time estimates between two nodes of the graph using the macro trend to obtain an updated graph, the two nodes of the graph representing the two of the different locations;
performing a fastest route analysis using the updated graph to obtain a fastest route; and
managing the traffic flow using the fastest route.

10. The non-transitory machine-readable medium of claim 9, wherein obtaining the macro trend comprises:
obtaining an image of a scene associated with an edge of the edges; and
ingesting the image into an inference model to obtain the macro trend.

11. The non-transitory machine-readable medium of claim 10, wherein the macro trend comprises one selected from a group consisting of:
a number of people in a queue in the scene; and
a number of people that pass by a point in the scene.

12. The non-transitory machine-readable medium of claim 10, where the inference model is programmed to identify a number of people in the scene.

13. The non-transitory machine-readable medium of claim 8, wherein adjusting the travel time estimate comprises:
obtaining, using the macro trend, a variable level of delay; and
obtaining the travel time estimate based on the variable level of delay and a static level of delay.

14. The non-transitory machine-readable medium of claim 13, wherein obtaining the updated graph comprises replacing a weight of an edge of the edges using the adjusted travel time estimate to obtain an updated edge of the edges.

15. A data processing system, comprising:
a processor; and
a memory coupled to the processor to store instructions, which when executed by the processor, cause the processor to perform operations for managing traffic flow in an environment based on macro trends, the operations comprising:
obtaining a graph, the graph representing the environment, the graph comprising:
nodes that are associated with different locations in the environment, and
edges connecting the nodes, the edges representing traversal times between the different locations associated with the nodes;
obtaining a macro trend of the macro trends, the macro trend indicating a level of foot traffic between two of the different locations, and the macro trend being obtained using computer vision;
adjusting a travel time estimate of the travel time estimates between two nodes of the graph using the macro trend to obtain an updated graph, the two nodes of the graph representing the two of the different locations;
performing a fastest route analysis using the updated graph to obtain a fastest route; and
managing the traffic flow using the fastest route.

16. The data processing system of claim 15, wherein obtaining the macro trend comprises:
obtaining an image of a scene associated with an edge of the edges; and
ingesting the image into an inference model to obtain the macro trend.

17. The data processing system of claim 16, wherein the macro trend comprises one selected from a group consisting of:
a number of people in a queue in the scene; and
a number of people that pass by a point in the scene.

18. The data processing system of claim 16, where the inference model is programmed to identify a number of people in the scene.

19. The data processing system of claim 15, wherein adjusting the travel time estimate comprises:
obtaining, using the macro trend, a variable level of delay; and
obtaining the travel time estimate based on the variable level of delay and a static level of delay.

20. The data processing system of claim 19, wherein obtaining the updated graph comprises replacing a weight of an edge of the edges using the adjusted travel time estimate to obtain an updated edge of the edges.
